(19) United States
(12) Patent Application Publication
(10) Pub. No.: US 2025/0133726 A1
(43) Pub. Date: Apr. 24, 2025

(54) DRAM DEVICE COMPRISING BIT LINE WITH REDUCED CAPACITANCE

(71) Applicant: Taesung Environmental Research Institute Co., Ltd., Ulsan (KR)

(72) Inventors: Gi Yeol YUN, Ulsan (KR); Seok Man Kim, Ulsan (KR); Chai Rok Lim, Ulsan (KR); Hyeok-Je Jeong, Gimhae-si (KR); Myung-Kon Jo, Ulsan (KR)

(73) Assignee: Taesung Environmental Research Institute Co., Ltd., Ulsan (KR)

(21) Appl. No.: 18/678,547

(22) Filed: May 30, 2024

(30) Foreign Application Priority Data
Oct. 20, 2023 (KR) 10-2023-0141176
Oct. 20, 2023 (KR) 10-2023-0141177

(51) Int. Cl. H10B 12/00

(52) U.S. Cl. CPC H10B 12/482; H10B 12/315

(57) ABSTRACT

A semiconductor device, comprising: a substrate; a plurality of bit lines located on the substrate, and disposed parallel to each other in a first horizontal direction at predetermined intervals; a plurality of word lines located on the bit line, and disposed parallel to each other in a second horizontal direction substantially perpendicular to the first horizontal direction at predetermined intervals; a plurality of channel patterns located on the bit line, spaced apart in a third horizontal direction different from the first and second horizontal directions and in a fourth horizontal direction substantially perpendicular to the third horizontal direction, and extending in a vertical direction; and a gate insulating pattern located between the plurality of channel patterns and the plurality of word lines, is disclosed.

### TECHNICAL FIELD

The present invention relates to a semiconductor device. More specifically, the present invention relates to a semiconductor device comprising a vertical channel transistor.

### BACKGROUND ART

As the density of semiconductor memory devices increases, the cell structure is changing from 8F2 and 6F2 to 4F2 in order to reduce the area occupied by each unit cell in a planar plane. As such, various methods have been suggested to form components such as transistors, bit lines, word lines, capacitors, etc. in response to the decrease in the area of the unit cell. In particular, in order to implement a 4F2 cell structure, a semiconductor device comprising a vertical channel transistor that induces a vertical channel by disposing a source and a drain vertically has been suggested (non-patent reference 1).

However, in the semiconductor device of non-patented reference 1, a channel pattern is disposed at every intersection of the bit line and the word line, causing too many channel patterns to be connected to a single bit line. As a result, the parasitic capacitance of the bit line increases, inevitably increasing the height of the cell capacitor to improve its capacitance. In addition, the sensing margin of the sense amplifier is reduced. This has resulted in decreased reliability of semiconductor devices and process disadvantages.

### PRIOR ART REFERENCE

### Non-Patent Reference

(Non-patent reference 1) Chung et al., “Novel 4F2 DRAM Cell with Vertical Pillar Transistor (VPT)” 2011 Proceedings of the European Solid-State Device Research Conference (ESSDERC), 2011

### SUMMARY OF INVENTION

### Technical Task

One of the many objects of the present invention is to provide a highly reliable and easy-to-manufacture vertical channel transistor and a semiconductor device comprising the same, by achieving increased sensing margin and reduced cell capacitor height from reduced bit line capacitance.

### Means for Solving Technical Task

According to an aspect, a semiconductor device, comprising: a substrate; a plurality of bit lines located on the substrate, and disposed parallel to each other in a first horizontal direction at predetermined intervals; a plurality of word lines located on the bit line, and disposed parallel to each other in a second horizontal direction substantially perpendicular to the first horizontal direction at predetermined intervals; a plurality of channel patterns located on the bit line, spaced apart in a third horizontal direction different from the first and second horizontal directions and in a fourth horizontal direction substantially perpendicular to the third horizontal direction, and extending in a vertical direction; and a gate insulating pattern located between the plurality of channel patterns and the plurality of word lines, is disclosed.

In an embodiment, an interval between adjacent word lines and an interval between adjacent bit lines may be substantially the same.

In an embodiment, the plurality of channel patterns located on a single bit line may be arranged in a straight line in a first horizontal direction.

In an embodiment, when an interval between adjacent word lines is L₁, an interval between adjacent bit lines is L₂, and an angle between the first horizontal direction and the third horizontal direction is θ₁, tan θ₁ may be L₂/L₁.

In an embodiment, when the number of total intersections of the word lines and the bit lines is n₁ and the number of intersections at which the channel pattern is disposed is n₂, n₁/n₂ may be 2.

In an embodiment, when an interval between adjacent word lines is L₁, an interval between adjacent bit lines is L₂, and an angle between the first horizontal direction and the third horizontal direction is θ₁, tan θ₁ may be 2L₂/L₁.

In an embodiment, when the number of total intersections of the word lines and the bit lines is n₁, and the number of intersections at which the channel pattern is disposed is n₂, n₁/n₂ may be 5.

### Effect of Invention

The vertical channel transistor according to the present invention and a semiconductor device comprising the same have the advantage of being capable of increasing the sensing margin of the sense amplifier as the parasitic capacitance of the bit line is reduced, and thus being more reliable.

In addition, the vertical channel transistor according to the present invention and a semiconductor device comprising the same have the advantage of facilitating manufacturing and scaling down as the height of the cell capacitor can be reduced.

The effects of an aspect of the present specification are not limited to the above-mentioned effects, and it should be understood that the effects of the present specification include all effects that could be inferred from the configuration described in the detailed description of the specification or the appended claims.

### BRIEF DESCRIPTION OF DRAWINGS

FIG. 1 is a perspective view of a vertical channel transistor according to an embodiment of the present invention;

FIG. 2 is a cross-sectional view taken along A-A′ of FIG. 1;

FIG. 3 is a schematic plan view of the vertical channel transistor of FIG. 1;

FIG. 4 is a perspective view of a semiconductor device comprising the vertical channel transistor of FIG. 1;

FIG. 5 is a perspective view of a vertical channel transistor according to another embodiment of the present invention;

FIG. 6 is a cross-sectional view taken along A-A′ of FIG. 5;

FIG. 7 is a schematic plan view of a vertical channel transistor according to another embodiment of the present invention; and

FIG. 8 is a perspective view of a semiconductor device comprising a vertical channel transistor according to another embodiment of the present invention.

### BEST MODE FOR CARRYING OUT THE INVENTION

Hereinafter, an aspect of the present invention will be explained with reference to the accompanying drawings. However, the present invention may be implemented in various different forms, and is not intended to be limited to the embodiments set forth herein.

Throughout the specification, it will be understood that when a portion is referred to as being “connected” to another portion, it can be “directly connected to” the other portion, or “indirectly connected to” the other portion having intervening portions present. In addition, when a member is referred to as being located “on,” “on an upper part of,” “on an upper end of,” “under,” “on a lower part of,” “on a lower end of” another member, this includes not only when a member is adjacent to another member, but also when there is another member between the two members.

Throughout this specification, when a component “includes” an element, unless there is another opposite description thereto, it should be understood that the component does not exclude another element but may further include another element.

The embodiments described herein will be described with reference to the cross-sectional views and/or schematic drawings, which are idealized illustrations of the present invention. In addition, throughout the specification, like reference numerals refer to like components. Detailed descriptions of known features and configurations which may obscure the gist of the present invention are hereby omitted, and each component in each of the drawings illustrating the present invention may be somewhat enlarged or reduced in size for ease of description.

Further, embodiments of the present invention are not limited to specific shapes illustrated, but also include variations in shape produced by the manufacturing process.

Hereinafter, with reference to the accompanying drawings, a vertical channel transistor according to an embodiment of the present invention will be described in detail.

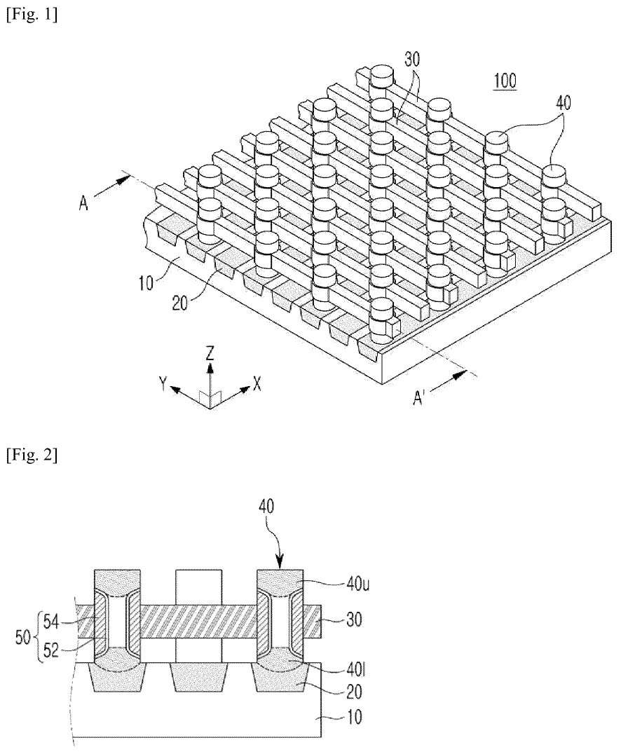

FIG. 1 is a perspective view of a vertical channel transistor according to an embodiment of the present invention.

Referring to FIG. 1, a vertical channel transistor 100 according to an embodiment of the present invention comprises: a substrate 10; a plurality of bit lines 20 located on the substrate 10, and disposed parallel to each other in a first horizontal direction at predetermined intervals; a plurality of word lines 30 located on the bit line 20, and disposed parallel to each other in a second horizontal direction substantially perpendicular to the first horizontal direction at predetermined intervals; a plurality of channel patterns 40 located on the bit line 20, spaced apart in a third horizontal direction different from the first and second horizontal directions and in a fourth horizontal direction substantially perpendicular to the third horizontal direction, and extending in a vertical direction; and a gate insulating pattern (not shown) located between the plurality of channel patterns 40 and the plurality of word lines 30. Here, the third and fourth horizontal directions are formed on a plane made in the first and second horizontal directions. In other words, the first to fourth horizontal directions are formed on a single plane (e.g., an XY plane).

The vertical channel transistor 100 according to an embodiment of the present invention has a plurality of bit lines 20 and a plurality of word lines 30 intersect each other. Each bit line 20 may extend in a first horizontal direction (e.g., an X-axis direction), and each word line 30 may extend in a second horizontal direction (e.g., a Y-axis direction) intersecting the first horizontal direction.

A plurality of channel patterns 40 are disposed at some points where the plurality of bit lines 20 and the plurality of word lines 30 intersect.

Electrodes (not shown) are formed, respectively, at an upper part and a lower part of the plurality of channel patterns 40. A gate (not shown) is formed to enclose a side surface between the upper electrode and the lower electrode, and the gate may comprise a gate insulating pattern and a gate conducing pattern.

FIG. 2 is a cross-sectional view taken along A-A′ of FIG. 1.

Referring to FIG. 2, the vertical channel transistor 100 comprises a substrate 10 and a plurality of channel patterns 40 arranged in an array on the substrate 10. The channel patterns 40 may be arranged in a two-dimensional array on a plane (e.g., an XY plane) of the substrate 10.

The substrate may include, for example, a group IV semiconductor material such as silicon (Si), germanium (Ge), silicon germanium (SiGe), silicon carbide (SiC), a group III-V semiconductor material such as gallium arsenide (GaAs), indium arsenide (InAs), indium phosphide (InP), an oxide semiconductor, a nitride semiconductor, a nitrogen oxide semiconductor, etc. Specifically, the substrate may be a silicon substrate doped with n-type impurities, but is not limited thereto.

Each of the plurality of channel patterns 40 may extend substantially vertically from the substrate 10. Here, each channel pattern 40 may protrude substantially vertically from an upper surface of the substrate 10. Each channel pattern 40 is integrally formed with the substrate 10, and thus may comprise the same semiconductor material as the substrate 10.

Each of the plurality of channel patterns 40 may comprise a source region as an upper electrode 40u and a drain region as a lower electrode 40l. The lower electrode 40l may be electrically connected to the bit line 20, and the upper electrode 40u may be electrically connected to a capacitor (not shown) which will be described later. The positions of the source region and the drain region may vary as needed, and the upper electrode 40u may function as a drain region and the lower electrode 40l may function as a source region.

In the channel pattern 40, the region between the upper electrode 40u and the lower electrode 40l, which is the body region (not shown), has the same polarity as the substrate 10, and the upper electrode 40u and the lower electrode 40l have a different polarity from the substrate 10. For example, when the substrate 10 is a p-type semiconductor substrate, the body region has a p-type polarity, and the upper electrode 40u and the lower electrode 40l have an n-type polarity. In this case, the upper electrode 40u and the lower electrode 40l may be formed by implanting n-type impurity ions into each of the upper end and the lower end of the channel pattern 40 and performing drive-in diffusion.

A gate 50 is formed between the upper electrode and the lower electrode to enclose a side surface of the channel pattern 40, and the gate 50 may comprise a gate insulating pattern 52 and a gate conducing pattern 54.

In an example, at least a portion of each channel pattern 40 may be in direct contact with the substrate 10. In this case, a back bias may be imparted to each channel pattern 40 to suppress the floating body effect. The contact area of each channel pattern 40 with the substrate 10 is not particularly limited, but may be, for example, any one of a periphery part or a center part of each channel pattern 40.

The bit lines 20 are arranged to extend along a first horizontal direction (e.g., an X-axis direction) on a lower part of the lower electrode 40l, and each bit line 20 may electrically connect the lower electrode 40l arranged along the first horizontal direction. The bit line 20 is formed in the interior of the substrate 10, and thus may comprise the same semiconductor material as the substrate 10.

Each of the plurality of word lines 30 is provided to correspond to a gate 50 formed on a side surface of the channel pattern. Specifically, each word line 30 may be provided to enclose the gate 50.

The word line 30 may comprise a conductive material. For example, the word line 30 may comprise at least one of metal, semiconductor and alloy. Specifically, the word line 30 may comprise one or more metals selected from the group consisting of aluminum, tungsten, molybdenum, titanium, and tantalum, and one or more semiconductors selected from the group consisting of group IV semiconductors, group III-V semiconductors, oxide semiconductors, nitride semiconductors, and nitrogen oxide semiconductors, but is not limited thereto.

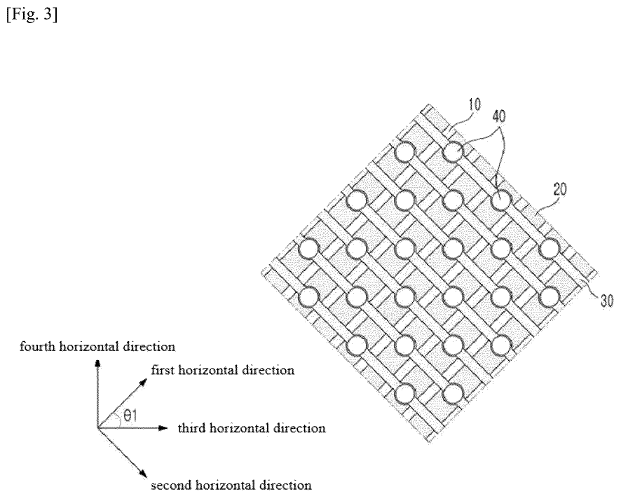

FIG. 3 is a schematic plan view of the vertical channel transistor of FIG. 1.

Referring to FIG. 3, the plurality of channel patterns 40 may be spaced apart in a third horizontal direction different from the first horizontal direction in which the plurality of bit lines 20 extend and the second horizontal direction in which the plurality of word lines 30 extend, and in a fourth horizontal direction substantially perpendicular to the third horizontal direction.

In conventional vertical channel transistors, the direction in which the bit lines and word lines are formed (e.g., X-axis direction and Y-axis direction) coincides with the direction in which the channel pattern array is arranged (e.g., X-axis direction and Y-axis direction). In other words, channel patterns are connected at every intersection of bit lines and word lines, causing too many channel patterns to be connected to a single bit line. As a result, the parasitic capacitance of the bit lines increase, inevitably increasing the height of the cell capacitor to improve its capacitance. In addition, the sensing margin of the sense amplifier is reduced. This has resulted in decreased reliability of semiconductor devices and process disadvantages.

However, according to the present invention, as the plurality of channel patterns 40 are arranged in a direction different from the direction in which the bit lines 20 and the word lines 30 are formed, the number of channel patterns disposed on a single bit line is reduced, and the number of cell transistors is reduced, thereby reducing the parasitic capacitance of the bit line. As a result, the sensing margin of the sense amplifier may increase or the height of the cell capacitor may be reduced, allowing increased reliability, and facilitating manufacturing and scaling down.

In an example, when the interval between adjacent word lines is L₁, the interval between adjacent bit lines is L₂, and the angle between the first horizontal direction and the third horizontal direction is θ₁, tan θ₁ may be L₂/L₁. Here, the interval between adjacent word lines means the length of a line segment connecting the center parts of two adjacent word lines when an imaginary line extending in a first horizontal direction is drawn from any point, and the interval between adjacent bit lines means the length of a line segment connecting the center parts of two adjacent bit lines when an imaginary line extending in a second horizontal direction is drawn from any point. In this case, since neighboring bit lines do not share word lines, there is an advantage of allowing cell arrays of a folded bit line structure. The folded bit line structure enables stable data sensing, increases the size of the cell array, and reduces the region of the sense amplifier, which may be advantageous in terms of cell efficiency.

When tan θ₁ has an excessively large value, the bit line interval must be reduced in order to dispose the same number of cells within the same area, resulting in an increase in the capacitance between neighboring bit lines and an increase in the difficulty of the bit line formation process. On the other hand, when tan θ₁ has a value of L₂/L₁, the bit line interval is relatively wide, resulting in low capacitance between neighboring bit lines and easy formation of bit lines.

In an example, L₁ and L₂ may have substantially the same value. In this case, the bit line capacitance may be minimized, and as a result, the height of the capacitor disposed on an upper part of the vertical channel transistor may be reduced, making scaling down easier.

In an example, the plurality of channel patterns placed on a single bit line may be arranged in a straight line in a first horizontal direction. In this case, the number of channel patterns disposed on a single bit line may be reduced and the number of cell transistors may be reduced, thereby reducing the parasitic capacitance of the bit line. As a result, the height of the capacitor disposed on an upper part of the vertical channel transistor may be reduced, making scaling down easier.

In an example, when the number of total intersections of the word lines and the bit lines is n₁, and the number of intersections at which the channel pattern is disposed is n₂, n₁/n₂ may be 2. Here, n₁/n₂ may mean the number of intersections located between adjacent channel patterns on a single bit line plus one. When n₁/n₂ has a value greater than 2, the bit line interval must be reduced in order to dispose the same number of cells within the same area, resulting in an increase in the capacitance between neighboring bit lines and an increase in the difficulty of the bit line formation process. On the other hand, when n₁/n₂ has a value of 2, the bit line interval is relatively wide, resulting in low capacitance between neighboring bit lines and easy formation of bit lines.

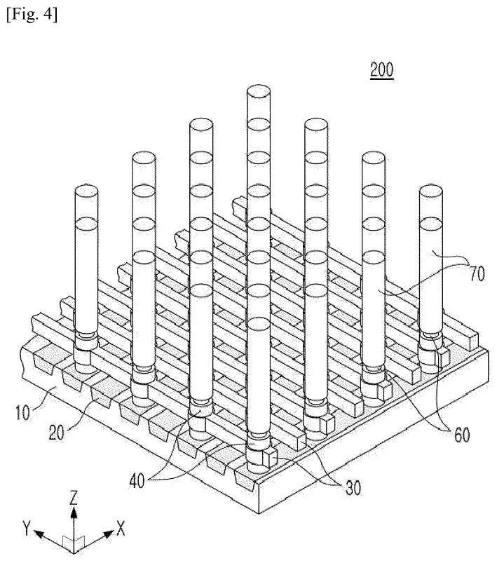

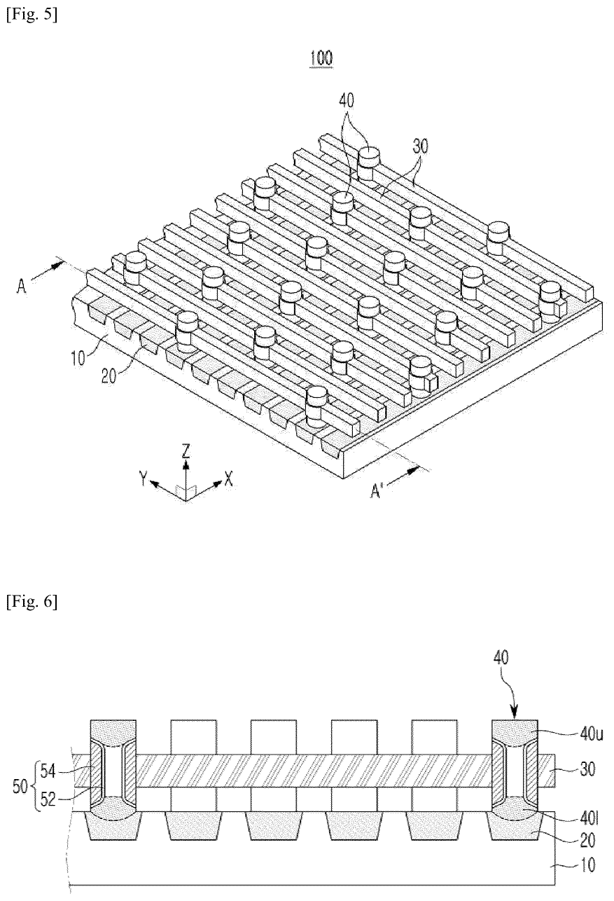

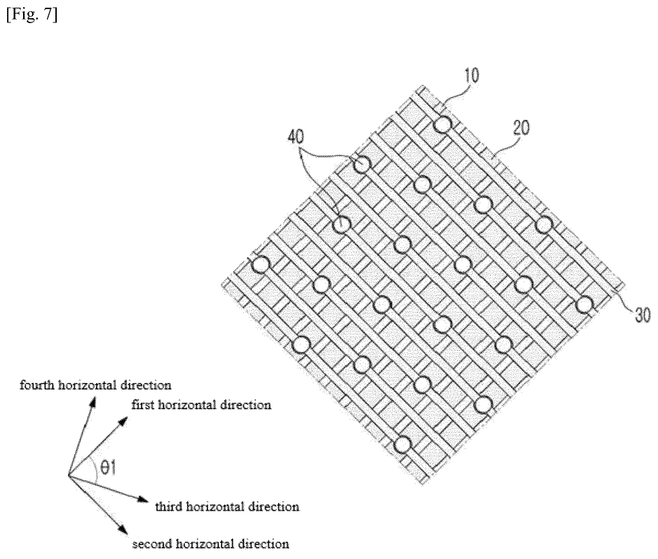

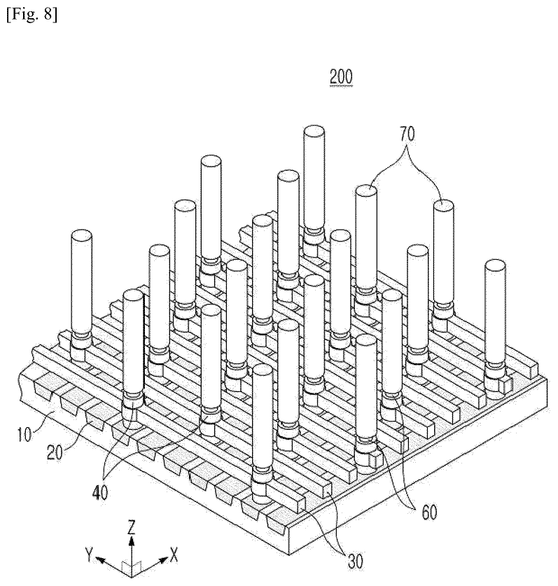

FIG. 4 is a perspective view of a semiconductor device comprising the vertical channel transistor of FIG. 1.

Referring to FIG. 4, a capacitor 70 is connected on the vertical channel transistor 100, through which a semiconductor device 200 such as a DRAM may be implemented.

The capacitor 70 may be electrically connected to the channel pattern 40, and a contact plug 60 may be further comprised between the capacitor 70 and the channel pattern 40. The vertical channel transistor 100 may be utilized in a non-memory such as a central processing unit (CPU), as well as in a memory as described above.

The present invention is not particularly limited to methods for manufacturing a vertical channel transistor and a semiconductor device comprising the same, but they may be manufactured by, for example, the following method.

On the substrate 10, a plurality of channel patterns 40 having electrodes 40u and 40l formed at an upper part and a lower part thereof and extending in a substantially vertical direction are formed. The upper electrode 40u of the plurality of channel patterns may be, for example, a source region, and the lower electrode 40l of the plurality of channel patterns may be, for example, a drain region.

The plurality of channel patterns 40 may be arranged in a two-dimensional array on a plane (e.g., an XY plane) of the substrate 10. Specifically, the channel patterns 40 may be arranged in a two-dimensional array equally spaced apart in the third horizontal direction on the plane (e.g., an XY plane) of the substrate 10 and in the fourth horizontal direction substantially perpendicular to the third horizontal direction.

Next, a gate 50 is formed to enclose a side surface between the upper electrode 40u and the lower electrode 40l of the plurality of channel patterns 40. The gate 50 may comprise a gate insulating pattern 52 and a gate conducing pattern 54.

Next, a plurality of bit lines 20 are formed to be in common contact with the lower electrode 40l of the plurality of channel patterns 40. Here, the bit lines 20 may be formed in a first horizontal direction (e.g., the X-axis direction in FIG. 1) which is different from the third horizontal direction and the fourth horizontal direction.

Next, a plurality of word lines 30 are formed to be in common contact with the gate 50 formed on a side surface of the plurality of channel patterns 40. Here, the word lines 30 may be formed in a second horizontal direction substantially perpendicular to the first horizontal direction.

Next, a series of subsequent processes known in the art may be performed one after the other to complete the manufacturing of a vertical channel transistor according to the present invention and a semiconductor device comprising the same.

Hereinafter, a vertical channel transistor according to another embodiment of the present invention will be described in detail with reference to the accompanying drawings. In the present embodiment, the angle between the first horizontal direction and the third horizontal direction has changed compared to the previous embodiment. Description overlapping with the previous embodiment will be omitted.

In another embodiment of the present invention, when the angle between the first horizontal direction and the third horizontal direction is θ₁, tan θ₁ is 2L₂/L₁.

When tan θ₁ has a value greater than 2L₂/L₁, the bit line interval must be reduced in order to dispose the same number of cells within the same area, resulting in an increase in the capacitance between neighboring bit lines and an increase in the difficulty of the bit line formation process. When tan θ₁ has a value smaller than 2L₂/L₁, the number of channel patterns and the number of cell transistors disposed on a single bit line may not be sufficiently reduced. On the other hand, when tan θ₁ has a value of 2L₂/L₁, it is possible to achieve an increase in the sensing margin of the sense amplifier and a decrease in the height of the cell capacitor while ensuring sufficient bit line interval.

In an example, when the number of total intersections of the word lines and the bit lines is n₁, and the number of intersections at which the channel pattern is disposed is n₂, n₁/n₂ may be 5. Here, n₁/n₂ may mean the number of intersections located between adjacent channel patterns on a single bit line plus one. When n₁/n₂ has a value greater than 5, the bit line interval must be reduced in order to dispose the same number of cells within the same area, resulting in an increase in the capacitance between neighboring bit lines and an increase in the difficulty of the bit line formation process. When n₁/n₂ has a value smaller than 5, the number of channel patterns and the number of cell transistors disposed on a single bit line may not be sufficiently reduced. On the other hand, when n₁/n₂ has a value of 5, it is possible to achieve an increase in the sensing margin of the sense amplifier and a decrease in the height of the cell capacitor while ensuring sufficient bit line interval.

The foregoing description of the present specification has been presented for illustrative purposes, and it is apparent to a person having ordinary skill in the art that the present specification can be easily modified into other detailed forms without changing the technical idea or essential features of the present specification. Therefore, it should be understood that the forgoing embodiments are by way of example only, and are not intended to limit the present specification. For example, each component which has been described as a unitary part can be implemented as distributed parts. Likewise, each component which has been described as distributed parts can also be implemented as a combined part.

The scope of the present specification is presented by the accompanying claims, and it should be understood that all changes or modifications derived from the definitions and scopes of the claims and their equivalents fall within the scope of the present specification.

### DESCRIPTION OF REFERENCE NUMERALS

10: substrate
20: bit line
30: word line
40: channel pattern
40l: lower electrode
40u: upper electrode
50: gate
52: gate insulating pattern
54: gate conducing pattern
60: contact plug
70: capacitor
100: vertical channel transistor
200: semiconductor device

What is claimed is:

1. A semiconductor device, comprising:
a substrate;
a plurality of bit lines located on the substrate, and disposed parallel to each other in a first horizontal direction at predetermined intervals;
a plurality of word lines located on the bit line, and disposed parallel to each other in a second horizontal direction substantially perpendicular to the first horizontal direction at predetermined intervals;
a plurality of channel patterns located on the bit line, spaced apart in a third horizontal direction different from the first and second horizontal directions and in a fourth horizontal direction substantially perpendicular to the third horizontal direction, and extending in a vertical direction; and
a gate insulating pattern located between the plurality of channel patterns and the plurality of word lines.

2. The semiconductor device of claim 1, wherein an interval between adjacent word lines and an interval between adjacent bit lines are substantially the same.

3. The semiconductor device of claim 1, wherein the plurality of channel patterns located on a single bit line are arranged in a straight line in a first horizontal direction.

4. The semiconductor device of claim 1, wherein when an interval between adjacent word lines is L₁, an interval between adjacent bit lines is L₂, and an angle between the first horizontal direction and the third direction is θ₁, tan θ₁ is L₂/L₁.

5. The semiconductor device of claim 4, wherein when the number of total intersections of the word lines and the bit lines is n₁, and the number of intersections at which the channel pattern is disposed is n₂, n₁/n₂ is 2.

6. The semiconductor device of claim 1, wherein when an interval between adjacent word lines is L₁, an interval between adjacent bit lines is L₂, and an angle between the first horizontal direction and the third horizontal direction is θ₁, tan θ₁ is 2L₂/L₁.

7. The semiconductor device of claim 6, wherein when the number of total intersections of the word lines and the bit lines is n₁, and the number of intersections at which the channel pattern is disposed is n₂, n₁/n₂ is 5.
